(19) United States
(12) Patent Application Publication
(10) Pub. No.: US 2026/0180306 A1
(43) Pub. Date: Jun. 25, 2026

(54) Failure detection circuit and failure detection device

(71) Applicant: INFSITRONIX TECHNOLOGY CORPORATION, Hsinchu County (TW)

(72) Inventors: Hui-Tsung Yang, Hsinchu County (TW); Chung-Chih Hung, Hsinchu County (TW); Wei-Chun Lu, Hsinchu County (TW)

(21) Appl. No.: 19/420,805

(22) Filed: Dec. 16, 2025

Related U.S. Application Data
(60) Provisional application No. 63/734,387, filed on Dec. 16, 2024.

(51) Int. Cl. H02H 1/00; G01R 31/34; G01R 31/56; H02H 7/08

(52) U.S. Cl. CPC H02H 1/0007; G01R 31/343; G01R 31/56; H02H 7/08

(57) ABSTRACT

The present application discloses a failure detection circuit and a failure detection device, which includes a switching circuit, a bias control circuit, and a fault detection circuit. The switching circuit has a first terminal, a second terminal, and a control terminal, and connects or disconnects the first and second terminals according to a control terminal voltage. The bias control circuit is coupled to the switching circuit and changes the control terminal voltage according to a fault signal. The fault detection circuit is coupled to the bias control circuit, detects an AC component in the control terminal voltage, and generates a fault signal according to the AC component. The fault detection circuit receives a detection signal, compares the detection signal, and generates a detection result signal. When the detection result signal is a fixed level signal or non-ripple signal, the fault detection circuit generates a fault signal.

### FIELD OF THE INVENTION

The present application relates to a failure detection circuit and a failure detection device, particularly to a failure detection circuit and a failure detection device for fan detection.

### BACKGROUND OF THE INVENTION

Fans in power supply systems, such as brushless direct current (BLDC) fans of two-wired type fans, have the advantages of simple structure and low cost. Because their power lines are composed of positive and negative power lines, coupled to voltage power capable of supplying the fans operating at full speed, enabling the fans to be easy to control. They are often used in environments with requirement of low heat dissipation or a fixed high-airflow and without fine speed adjustment, such as chassis fans or small household appliances. However, a disadvantage is that the fan speeds of the fans cannot be detected. When the fan cannot rotate due to the fan bearing being damaged or the fan blades being jammed by external force, the fan inductor coil may saturate and fail to generate back electromotive force, resulting in presenting a low-resistance state in the fan drive coil and occurring a large current appearance in a driving circuit, such as potentially increasing to tens to hundreds of milliamps, causing permanent damage to the fan or the driving circuit, and possibly even damaging the main system of passive heat dissipation. Furthermore, in marketing, different power supply systems use cooling fans in different fan specifications, judging whether a fault has occurred based on voltage or current magnitude is not applicable to all fans.

### SUMMARY

An object of the present application is to provide a fault detection circuit, comprising a first input terminal and a second input terminal. The first input terminal receives a first detection signal, and the second input terminal receives a second detection signal. The fault detection circuit compares the first detection signal with the second detection signal and generates a detection result signal. When the detection result signal is a fixed level signal or a non-ripple signal, the fault detection circuit outputs a fault signal, achieving an immediate fault protection effect.

An object of the present application is to provide a fault detection circuit, comprising a first input terminal, a sampling unit, and a comparator. The first input terminal receives the first detection signal. The sampling unit is coupled to the first input terminal and generates an average detection signal based on the first detection signal. The comparator is coupled to the sampling unit and compares the first detection signal with the average detection signal, generating a detection result signal. When the detection result signal is a fixed level signal or a non-ripple signal, the fault detection circuit outputs a fault signal, achieving an immediate fault protection effect.

An object of the present application is to provide a fault detection device, which includes a switching circuit, a bias control circuit, and a fault detection circuit. The switching circuit has a first terminal, a second terminal, and a control terminal. The switching circuit switches a connection between the first terminal and the second terminal on or off according to a control terminal voltage at the control terminal. The bias control circuit is coupled to the switching circuit and changes the control terminal voltage according to a fault signal. The fault detection circuit is coupled to the bias control circuit, detects an AC component in the control terminal voltage, and generates the fault signal based on the AC component in the control terminal voltage. Even if the fan cannot directly provide a rotation speed information, it may achieve real-time fault protection by detecting the AC component in the control terminal voltage at the switching circuit.

### BRIEF DESCRIPTION OF THE DRAWINGS

FIG. 1: which is an architectural schematic diagram of a fault detection device according to an embodiment of the present application.

FIG. 2: which is a circuit schematic diagram of a fault detection device according to a first embodiment of the present application.

FIG. 3: which is a circuit schematic diagram of a fault detection device according to a second embodiment of the present application.

### DETAILED DESCRIPTION

To provide the esteemed examiners with a further understanding and recognition of the features and effects achieved by the present application, detailed explanations are provided in conjunction with embodiments as follows:

Certain terms used in the specification and claims refer to specific components; however, those skilled in the art should understand that manufacturers may use different terms to refer to the same component, and furthermore, the specification and claims do not distinguish components based on the difference in names, but rather on the differences in the components in terms of overall technology. Throughout the specification and claims, the term “comprising” is an open-ended term and should be interpreted as “including but not limited to.” Moreover, the term “coupled” herein includes any means of direct and indirect connection. Therefore, if the text describes a first device coupled to a second device, it means that the first device may be directly connected to the second device, or may be indirectly connected to the second device through other devices or means of connection.

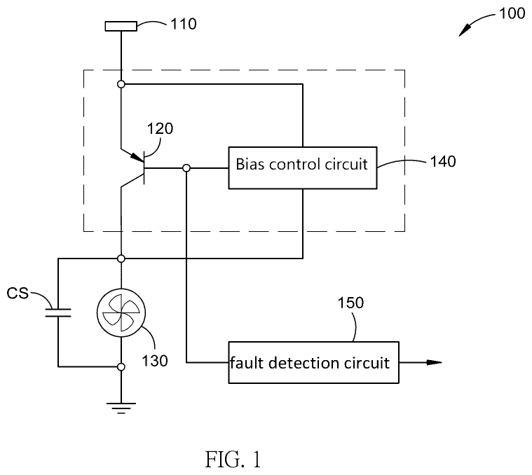

Please refer to FIG. 1, which is an architectural schematic diagram of a fault detection device according to an embodiment of the present application. The fault detection device according to the present application is used for short-circuit protection. The fault detection device 100 comprises a power supply 110, a switching circuit 120, a load 130, a capacitor CS, a bias control circuit 140, and a fault detection circuit 150. The power supply 110 is coupled to the load 130 via the switching circuit 120, the bias control circuit 140 is coupled to the switching circuit 120, and the fault detection circuit 150 is coupled to both the switching circuit 120 and the bias control circuit 140. In this embodiment, the load 130 is a cooling fan, such as a two-wired type fan.

In this embodiment, the switching circuit 120 includes a first terminal, a second terminal, and a control terminal. The first terminal of the switching circuit 120 is coupled to the power supply 110 and the bias control circuit 140, the second terminal of the switching circuit 120 is coupled to the load 130, and the control terminal of the switching circuit 120 is coupled to both the bias control circuit 140 and the fault detection circuit 150. The bias control circuit 140 switches the switching circuit 120 on or off based on a control terminal voltage at the control terminal of the switching circuit 120. For example, when the fault detection circuit 150 detects the control terminal voltage in abnormal, the fault detection circuit 150 outputs a fault signal to the bias control circuit 140. After the bias control circuit 140 receives the fault signal, the bias control circuit changes the control terminal voltage to switch the switching circuit 120 off, thereby breaking the connection between the power supply 110 and the load 130, achieving the functions of fault detection and circuit protection. The capacitor CS is a voltage regulator capacitor.

Specifically, the fault detection circuit 150 may detect an AC component in the control terminal voltage. When the load 130 is a fan, the AC component in the control terminal voltage may represent information such as fan speed and frequency. When the fan is operating normally, the AC component in the control terminal voltage may show a fluctuating waveform. When the fan malfunctions, such as when the fan is stuck, the AC component in the control terminal voltage may show a fixed level or the control terminal voltage may be a non-ripple signal, such as maintaining a high level or a low level. When the fault detection circuit 150 detects that the AC component in the control terminal voltage is a fixed level signal or a non-ripple signal, the fault detection circuit 150 generates a fault signal and outputs the fault signal to the bias control circuit 140. The bias control circuit 140 changes the control terminal voltage according to the fault signal, causing the first terminal and the second terminal of the switching circuit 120 to be switched off. In this embodiment, the switching circuit 120 and the bias control circuit 140 are formed as a load drive circuit, such as a fan drive circuit, as shown by the dashed box in FIG. 1.

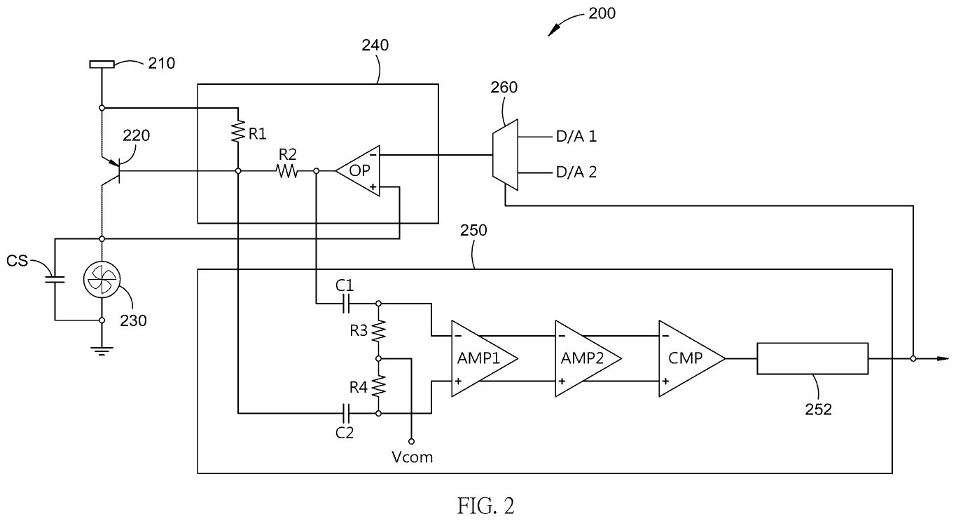

Please refer to FIG. 2, which is a circuit schematic diagram of a fault detection device according to a first embodiment of the present application. The fault detection device 200 comprises a power supply 210, a switching circuit 220, a load 230, a capacitor CS, a bias control circuit 240, a fault detection circuit 250, and a bias selection circuit 260.

The bias control circuit 240 comprises a first resistor R1, a second resistor R2, and an operational amplifier OP. The first resistor R1 is coupled to a first terminal of the switching circuit 220, and the second resistor R2 is coupled to a control terminal of the switching circuit 220, and has a control terminal voltage. The operational amplifier OP is coupled to the bias selection circuit 260, and outputs a first bias voltage D/A1 or a second bias voltage D/A1 to the control terminal of the switching circuit 220 to change the control terminal voltage.

The fault detection circuit 250 comprises a first input terminal, a second input terminal, a first capacitor C1, a second capacitor C2, a third resistor R3, a fourth resistor R4, operational amplifiers AMP1 and AMP2, a comparator CMP, and a digital counting filter 252. The first input terminal is coupled to one end of the second resistor R2, and receives a voltage or a current at one end of the second resistor R2 as a first detection signal. The second input terminal is coupled to the other end of the second resistor R2, and receives the voltage or the current at the other end of the second resistor R2 as a second detection signal. In this embodiment, the impedance inside the fault detection circuit 250 is illustrated using resistors and capacitors as exemplified. The present application is not limited thereto, the first capacitor C1, the second capacitor C2, the third resistor R3, and the fourth resistor R4 may be selected from other impedance components.

The first capacitor C1 is coupled to the first input terminal and converts the first detection signal into a first AC signal. The second capacitor C2 is coupled to the second input terminal and converts the second detection signal into a second AC signal. That is, the DC component in the first and second detection signals is filtered out by the first capacitor C1 and the second capacitor C2, while retaining the AC component in the first and second detection signals. In this embodiment, the voltage levels of the first and second AC signals are located at a bias voltage of a common-mode voltage Vcom of the first AC signal. The first and second AC signals may be correctly amplified at the bias voltage of the common-mode voltage Vcom, thereby achieving the effect of signal amplification.

The third resistor R3 and the fourth resistor R4 perform a voltage division to form the common-mode voltage Vcom of the operational amplifier AMP1. The first AC signal (the AC component in the first detection signal) and the second AC signal (the AC component in the second detection signal) are input to the operational amplifier AMP1. The operational amplifier AMP1 acts as a differential amplifier, amplifying the first and second AC signals and outputting them to subsequent circuits. In this embodiment, the fault detection circuit 250 further comprises the operational amplifier AMP2. The first and second AC signals are amplified by operational amplifiers AMP1 and AMP2 and outputted to the comparator CMP. The number of the operational amplifiers may be adjusted according to actual needs. Amplifying signals through multiple operational amplifiers increases the accuracy of subsequent circuits, thereby, allowing the comparator CMP to correctly compare the difference between the first and second AC signals.

The comparator CMP compares the difference between the first AC signal and the second AC signal and outputs a detection result signal. When the fan malfunctions, such as when the fan is stuck, the first AC signal and the second AC signal may present fixed level signals or non-ripple signals, such as maintaining a high level or a low level. When the first AC signal and the second AC signal are fixed level or non-ripple signals, the detection result signal output by the comparator CMP may be a low level signal. The digital counting filter 252 receives the detection result signal and sends a normal signal or a fault signal according to the detection result signal. When the detection result signal is a low level signal, the digital counting filter 252 generates a fault signal to the bias selection circuit 260. The digital counting filter 252 may be set with a detection period and an overdue time (TIME OUT). If the waveform output by the comparator CMP matches the set period, it is determined that the fan is working normally. If the overdue time is exceeded, it is determined that the fan has malfunctioned. In another embodiment, the detection result signal output by the comparator CMP may be a high-level signal. When the detection result signal is a high-level signal, the digit counting filter 252 generates a fault signal to the bias selection circuit 260.

The bias selection circuit 260 is coupled to the bias control circuit 240, the bias selection circuit 260 selects the first bias voltage D/A1 or the second bias voltage D/A2 according to the fault signal, and outputs the selected bias voltage to the bias control circuit 240 to change the control terminal voltage. For example, the first bias voltage D/A1 is a bias voltage supplied to the switching circuit 220 when the load 230 is operating normally, and the second bias voltage D/A2 is a bias voltage supplied to the switching circuit 220 when the load 230 is failure. When the load 230 operates normally, the fault detection circuit 250 outputs a normal signal to the bias selection circuit 260, causing the bias selection circuit 260 to select the first bias voltage D/A1 and supply the first bias voltage D/A1 to the control terminal, thereby changing the control terminal voltage and turning on the switch circuit 220. When the load 230 malfunctions, fault detection circuit 250 outputs a fault signal to the bias selection circuit 260, causing the bias selection circuit 260 to select the second bias voltage D/A2 and supply the second bias voltage D/A2 to the control terminal, thereby changing the control terminal voltage and turning off the switch circuit 220. In this embodiment, the first bias voltage D/A1 may be a low-level voltage, and the second bias voltage D/A2 may be a high-level voltage. In other embodiments, the first bias voltage D/A1 may be a high-level voltage, and the second bias voltage D/A2 may be a low-level voltage. In this embodiment, the bias selection circuit 260 may be implemented by a multiplexer (MUX) to select one from multiple input signals and output the selected input signal.

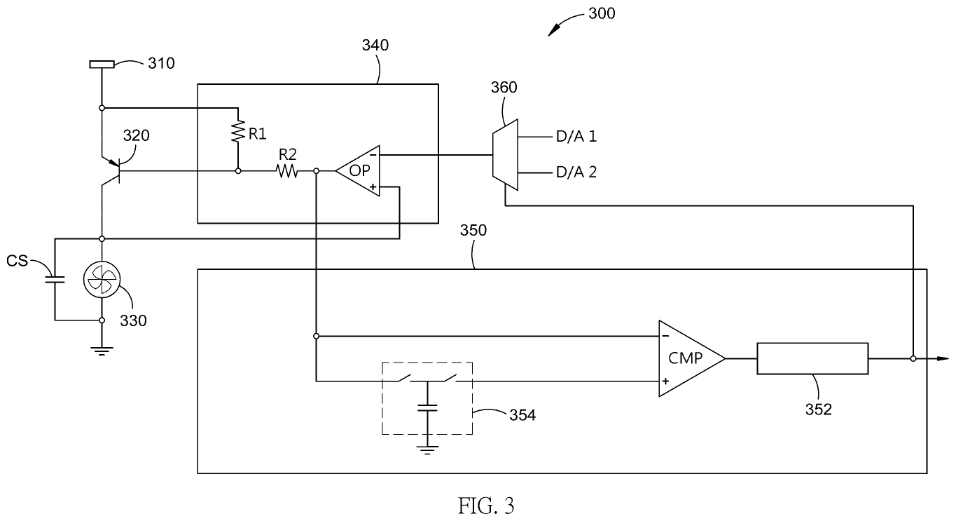

Please refer to FIG. 3, which is a circuit schematic diagram of a fault detection device according to a second embodiment of the present application. The fault detection device 300 comprises a power supply 310, a switching circuit 320, a load 330, a capacitor CS, a bias control circuit 340, a fault detection circuit 350, and a bias selection circuit 360. The circuit architecture and operation of the bias control circuit 340 and the bias selection circuit 360 are the same as those in the second embodiment, and may not be described here, again.

The fault detection circuit 350 comprises a first input terminal, a sampling unit 354, a comparator CMP, and a digital counting filter 352. The first input terminal is coupled to one end of the resistor R2 of the bias control circuit 340, and receives the voltage or current at one end of the second resistor R2 as the first detection signal. The sampling unit 354 is coupled to the first input terminal and generates an average detection signal based on the first detection signal. The comparator CMP is coupled to the sampling unit 354, compares the first detection signal with the average detection signal, and generates a detection result signal. When the detection result signal is a fixed level signal or a non-ripple signal, the fault detection circuit 350 outputs a fault signal. In this embodiment, the comparator CMP may be implemented using an operational amplifier, comparing the signals at both the positive and negative input terminals.

In this embodiment, the sampling unit 354 is a sample and hold circuit, continuously obtaining the first detection signal at the previous period, for example, obtaining the maximum or minimum value of the first detection signal and generating an average detection signal. The sampling unit 354 generates the average detection signal according to a sampling frequency greater than a signal frequency of the first detection signal, for example, a sampling frequency greater than 10 times the signal frequency of the first detection signal. The comparator CMP receives the values of the first detection signal at the previous period generated by the sampling unit 354 and the first detection signal at the current time, continuously comparing the difference between the two values. When there is a difference between the two values, it is indicative of the load 320 operating in normal. When the voltage difference between the two values approaches a setting value, it is indicative of the load 320 operating in malfunctioning and requiring the protection.

In the present application, the switching circuits 120, 220, and 320 may be implemented using bipolar junction transistors (BJTs), such as P-type or N-type BJTs, or other types of transistors, such as field-effect transistors (FETs). The present application is not limited thereto. The resistance values of the first resistor R1 and the second resistor R2 are, for example, 1K to 100K ohms, and the resistance values of the third resistor R3 and the fourth resistor R4 are, for example, 1M ohms. The resistance values of the third resistor R3 and the fourth resistor R4 are greater than the resistance values of the first resistor R1 and the second resistor R2.

Through the fault detection circuit and fault detection device of the present application, a load fault condition may be automatically detected, such as a fan lock-up state. A fault signal is outputted, and the bias control circuit may be automatically shut down or restarted to protect the passive cooling main system and the bias control circuit. Furthermore, when the fault detection circuit and the fault detection device of the present application are applied to a two-wired fan system, even if the fan cannot directly provide the rotation speed information, real-time fault protection may be achieved by detecting the AC component in the control terminal voltage of the switching circuit, enabling fan fault protection without the need for additional circuitry. Moreover, since the fault detection device of the present application does not need to detect the magnitude of voltage or current of the fan to determine whether a fault has occurred, but rather detects the AC component in the voltage or current, which is applicable to all fan devices of all fan specifications. Different fault detection devices and different fault detection circuits do not need to be replaced for different fan specifications, significantly reducing costs.

Therefore, the present application indeed possesses novelty, progressiveness, and industrial applicability, undoubtedly meeting the requirements for a patent application under the national patent law. Accordingly, a patent application has been legally filed, earnestly praying for the patent application grant to be issued soon.

However, the above description is merely an embodiment of the present application and is not intended to limit the scope of the present application. Therefore, all equivalent modifications and variations according to the structure, and the features described in the scope of the patent application should be included within the scope of this patent application.

What is claimed is:

1. A fault detection circuit comprising:
a first input terminal, receiving a first detection signal; and
a second input terminal, receiving a second detection signal, wherein the fault detection circuit compares the first detection signal with the second detection signal and generates a detection result signal, and when the detection result signal is a fixed level signal or a non-ripple signal, the fault detection circuit outputs a fault signal.

2. The fault detection circuit of claim 1, further comprising:
a first capacitor, coupled to the first input terminal, and converting the first detection signal into a first AC signal; and
a second capacitor, coupled to the second input terminal, and converting the second detection signal into a second AC signal.

3. The fault detection circuit of claim 2, further comprising:
an operational amplifier, coupled to the first capacitor and the second capacitor, and receiving the first AC signal and the second AC signal; and
a comparator, coupled to the amplifier, comparing the first AC signal with the second AC signal, and outputting the detection result signal.

4. The fault detection circuit of claim 3, further comprising:
a digital counting filter, coupled to the comparator, and outputting the fault signal based on the detection result signal.

5. A fault detection circuit, comprising:
a first input terminal, receiving a first detection signal;
a sampling unit, coupled to the first input terminal, and generating an average detection signal based on the first detection signal; and
a comparator, coupled to the sampling unit, comparing the first detection signal with the average detection signal, and generating a detection result signal, wherein the fault detection circuit outputs a fault signal when the detection result signal is a fixed level signal or a non-ripple signal.

6. The fault detection circuit of claim 5, wherein the sampling unit obtains the maximum and minimum values of the first detection signal and generates the average detection signal.

7. The fault detection circuit of claim 5, wherein the sampling unit generates the average detection signal according to a sampling frequency, the sampling frequency is greater than a signal frequency of the first detection signal.

8. The fault detection circuit of claim 7, wherein the sampling frequency is greater than 10 times the signal frequency of the first detection signal.

9. A fault detection device comprising:
a switching circuit, including a first terminal, a second terminal, and a control terminal, the control terminal including a control terminal voltage, the switching circuit switching a connection between the first terminal and the second terminal on or off according to the control terminal voltage;
a bias control circuit, coupled to the switching circuit, changing the control terminal voltage according to a fault signal; and
a fault detection circuit, coupled to the bias control circuit, detecting an AC component in the control terminal voltage, and generating the fault signal according to the AC component in the control terminal voltage.

10. The fault detection device of claim 9, wherein the bias control circuit comprises a first resistor and a second resistor, the first resistor is coupled to the first terminal, and the second resistor is coupled to the control terminal, the second resistor ha the control terminal voltage.

11. The fault detection device of claim 9, further comprises:
a bias selection circuit, coupled to the bias control circuit, wherein a first bias voltage or a second bias voltage is selected and output to the bias control circuit to change the control terminal voltage according to the fault signal.

12. The fault detection device of claim 11, wherein the bias control circuit comprises an operational amplifier, the operational amplifier is coupled to the bias selection circuit, the operational amplifier outputs the first bias voltage or the second bias voltage to the switching circuit to change the control terminal voltage.
